(19) United States
(12) Patent Application Publication
(10) Pub. No.: US 2004/0014323 A1
(43) Pub. Date: Jan. 22, 2004

(54) Method of fabricating semiconductor device

(75) Inventor: Shu Shimizu, Hyogo (JP)

Correspondence Address: McDERMOTT, WILL & EMERY, 600 13th Street, N.W., Washington, DE, 20005-3096, US

(73) Assignee: MITSUBISHI DENKI KABUSHIKI KAISHA

(21) Appl. No.: 10/338,643

(22) Filed: Jan. 9, 2003

(30) Foreign Application Priority Data
Jul. 19, 2002 (JP) 2002-211211

(51) Int. Cl. H01L 21/311

(52) U.S. Cl. 438/694

(57) ABSTRACT

In a method of fabricating a semiconductor device according to the present invention, a portion including a prospective electrode contact hole forming region of a patterning insulator film located on a gate electrode of a transistor to be formed with an electrode contact on the gate electrode is selectively simultaneously removed in an etching step for an element isolation film for implementing a self-aligned source structure forming a source line in a self-aligned manner with respect to the gate electrode, for partially exposing the upper surface of the gate electrode. Thus, both of a substrate contact hole and an electrode contact hole can be simultaneously formed without increasing the number of fabrication steps, while the number of masks can be reduced.

### BACKGROUND OF THE INVENTION

1. Field of the Invention

The present invention relates to a method of fabricating a semiconductor device, and more particularly, it relates to a method of fabricating a nonvolatile semiconductor memory device having a self-aligned source structure.

2. Description of the Background Art

A flash memory included in nonvolatile semiconductor memory devices, which can be fabricated at a lower cost than a dynamic random access memory (DRAM), is watched with interest as an advanced memory device. A memory cell of such a flash memory comprises a source region connected to a corresponding source line, a drain region connected to a corresponding bit line, a floating gate electrode for storing information and a control gate electrode connected to a corresponding word line.

In general, a floating-gate nonvolatile semiconductor device such as the flash memory or an EEPROM (electrically erasable and programmable read only memory) having a floating gate electrode employs a self-aligned source structure.

In the self-aligned source structure, no substrate contacts are formed on diffusion layers of memory cell transistors to be connected with each other by conductor wires but a diffusion layer wire is employed for connecting source regions of the memory cell transistors with each other without substrate contacts. The diffusion layer wire is obtained by removing an element isolation film located between the source regions by etching and forming an impurity diffusion layer having a conductivity type corresponding to the source regions on the main surface of a semiconductor substrate from which the element isolation film is removed by ion implantation, for connecting the source regions of the memory cell transistors with each other. In general, this diffusion layer wire is referred to as a source line.

Following recent refinement of semiconductor devices, a fabrication process for a semiconductor device essentially requires a self-aligned contact structure. The aforementioned floating-gate nonvolatile semiconductor memory device having a floating gate electrode is no exception but generally employs the self-aligned contact structure.

In the self-aligned contact structure, substrate contacts can be formed on a source region and a drain region in a self-aligned manner, and fine contacts can be reliably formed also when a mask is misaligned. The self-aligned contact structure includes a structure of forming a substrate contact in a self-aligned manner with respect to a gate electrode while ensuring insulation between the gate electrode and the substrate contact and a structure preventing an element isolation film adjacent to a source region or a drain region from false etching when forming a substrate contact hole.

In the self-aligned contact structure forming the substrate contact in a self-aligned manner with respect to the gate electrode while ensuring insulation between the gate electrode and the substrate contact, the gate electrode is previously covered with an insulator film such as a nitride film for stopping etching with this insulator film when forming a substrate contact hole. When the gate electrode is previously covered with an etching stopper film as described above, the substrate contact is formed in a self-aligned manner with respect to the gate electrode also when the mask is misaligned.

In the self-aligned contact structure preventing the element isolation film adjacent to the source region or the drain region from false etching when forming the substrate contact hole, a thin nitride film is deposited on a lower layer portion of an interlayer insulation film to be formed with the substrate contact for temporarily stopping etching for forming a substrate contact hole by the nitride film and optimizing etching conditions for etching the nitride film and an underlayer oxide film. Thus, etching is performed in two stages for forming the substrate contact hole, thereby preventing the element isolation film from misetching resulting from overetching.

As hereinabove described, the recent process of fabricating a nonvolatile semiconductor memory device increasingly requires the self-aligned source structure and the self-aligned contact structure for refining the nonvolatile semiconductor memory device.

A flash memory is now illustrated as a conventional nonvolatile semiconductor memory device having the aforementioned self-aligned source structure and the aforementioned self-aligned contact structure, and the structure thereof is described in detail.

As shown in FIG. 13, the flash memory generally has a memory cell region and a peripheral circuit region on the same silicon substrate. The gate electrode of each memory cell transistor formed on the memory cell region consists of a floating gate electrode 113 located on the main surface of a silicon substrate 101 through a tunnel oxide film 106 and a control gate electrode 114 located on the floating gate electrode 113 through an ONO (oxide nitride oxide) film 108 consisting of an oxide film, a nitride film and an oxide film. The upper portion of the control gate electrode 114 is covered with a tungsten silicide (WSi) film 111.

The upper surface and the side surfaces of the gate electrode of the memory cell transistor having the aforementioned structure are covered with an insulator film 112 for patterning the gate electrode and side wall insulator films 122 respectively. The patterning insulator film 112 and the side wall insulator films 122 are formed by oxide-based insulator films. When the self-aligned contact structure is employed for forming a substrate contact in a self-aligned manner with respect to the gate electrode, multilayer films consisting of oxide-based insulator films and nitride-based insulator films formed thereon are employed as the patterning insulator film 112 and the side wall insulator films 122. The oxide-based insulator films are formed under the nitride-based insulator films in order to relax intrinsic stress of the nitride-based insulator films by the oxide-based insulator films so that stress applied to the gate electrode can be remarkably relaxed by forming the underlayer oxide-based insulator films as compared with a case of directly depositing nitride-based insulator films on the gate electrode.

A source region 116 and a drain region 117 are formed on portions of the main surface of the silicon substrate 101 holding the gate electrode of the memory cell transistor therebetween. A substrate contact 128 is individually formed on the drain region 117 every memory cell, and connected to a corresponding bit line. No substrate contact is provided on the source region 116, which is connected to a source region adjacent thereto perpendicularly to the plane of the figure by a source line 118 serving as a diffusion layer wire (see FIG. 15).

A gate electrode 115 of each peripheral circuit transistor formed on the peripheral circuit region is located on the main surface of the silicon substrate 101 through a tunnel oxide film 109. The gate electrode l of the peripheral circuit transistor has a structure identical to the gate electrode structure of a general MOS (metal oxide semiconductor), dissimilarly to the gate electrode of the aforementioned memory cell transistor. The upper portion of the gate electrode 115 of the peripheral circuit transistor is also covered with a tungsten silicide film 111.

The upper surface and the side surfaces of the gate electrode 115 of the peripheral circuit transistor having the aforementioned structure are covered with an insulator film 112 for patterning the gate electrode 115 and side wall insulator films 112 respectively. The patterning insulator film 112 and the side wall insulator films 122 are formed by oxide-based insulator films. When the self-aligned contact structure is employed for forming a substrate contact in a self-aligned manner with respect to the gate electrode 115, multilayer films consisting of oxide-based insulator films and nitride-based insulator films are employed in place of the oxide-based insulator films.

Source regions 119a and 119b and drain regions 120a and 120b are provided on portions of the main surface of the silicon substrate 101 holding the gate electrode 115 of the peripheral circuit transistor therebetween. Substrate contacts 128 are formed on the source regions 119a and 119b and the drain regions 120a and 120b respectively and connected to wires corresponding thereto. In the peripheral circuit transistor, no self-aligned source structure is employed for connecting the source regions 119a and 119b to other source regions, and hence the substrate contact 128 is individually formed on the source regions 119a and 119b. An electrode contact 129 is formed on the gate electrode 115 of the peripheral circuit transistor.

All of the substrate contact 128 of the aforementioned memory cell transistor as well as the substrate contacts 128 and the electrode contact 129 of the aforementioned peripheral circuit transistor are formed to pass through an interlayer insulation film deposited to cover the gate electrodes and the main surface of the silicon substrate 101. In order to prevent an element isolation film from misetching by the self-aligned contact structure, the interlayer insulation film is formed by three layers including a first oxide-based insulator film 123, a nitride-based insulator film 124 and a second oxide-based insulator film 125. The nitride-based insulator film 124 is formed for preventing the element isolation film from misetching in a step of forming substrate contact holes when employing the aforementioned self-aligned contact structure, and the first oxide-based insulator film 123 serves as an underlayer for the nitride-based insulator film 124.

In fabrication of the nonvolatile semiconductor memory device having the aforementioned structure, fabrication steps are desirably simplified to a minimum in order to reduce the fabrication cost. When the self-aligned contact structure is employed, however, a substrate contact hole provided on an active region and an electrode contact hole provided on a gate electrode cannot be simultaneously formed. In general, therefore, these contact holes are formed in different steps, leading to complication of the fabrication steps and increase of the fabrication cost.

A method of fabricating the conventional flash memory having the aforementioned structure is now described along with detailed description of the reason why the substrate contact hole and the electrode contact hole cannot be simultaneously formed as described above.

Referring to FIG. 14, element isolation films 105 are selectively formed on the main surface of the silicon substrate 101, for forming an active region and element isolation regions. Then, the gate electrode consisting of a layer-built electrode of the floating gate electrode 113 and the control gate electrode 114 is formed on the memory cell region while the gate electrode 115 having the same structure as that of a general MOS transistor is formed on the peripheral circuit region. The patterning insulator films 112 employed for patterning the gate electrode and the gate electrode 115 remain on the gate electrode and the gate electrode 115 to cover the upper surfaces thereof.

Referring to FIG. 15, resist films 131 are formed to cover the overall peripheral circuit region and the drain region part of the memory cell region and employed as masks for removing the element isolation film 105 located between the source region 116 and the adjacent source region of the memory cell region by etching. Then, ions are implanted into the portion of the main surface of the silicon substrate 101 from which the element isolation film 105 is removed, thereby forming a diffusion layer having a conductivity type corresponding to the source region 116. Thus, the source line 118 is formed to connect the source region 116 with the source region adjacent thereto along the gate width direction, as shown in FIG. 15. The section of the memory cell region in the gate width direction shown in FIG. 15 is taken along the dotted line 150 on the section of the memory cell region along the gate length direction.

Referring to FIG. 16, the resist films 131 are removed for thereafter forming extension layers 119a and 120a for partially forming the source and drain regions 119a and 120a of the peripheral circuit transistor respectively by ion implantation. Then, the side wall insulator films 122 are formed and employed as masks for forming diffusion layer regions 119b and 120b for defining the source and drain regions 119b and 120b respectively by ion implantation. Thereafter the first oxide-based insulator film 123, the nitride-based insulator film 124 and the second oxide-based insulator film 125 are successively deposited on the overall main surface of the silicon substrate 101, for forming the interlayer insulation film.

Referring to FIG. 17, a patterned resist film 132 is deposited on the interlayer insulation film and employed as a mask for selectively removing portions of the interlayer insulation film for defining the substrate contacts 128 and forming substrate contact holes 126. At this time, the interlayer insulation film is etched through two steps of partially removing the second oxide-based insulator film 125 under an etching condition having selectivity for the nitride-based insulator film 124 and removing the remaining portions of the nitride-based insulator film 124 while partially removing the first oxide-based insulator film 123 under an etching condition different from the aforementioned one. Thus, the quantity of overetching can be suppressed as compared with a case of etching the interlayer insulation film at a time, whereby the element isolation films 105 adjacent to the formed substrate contact holes 126 are prevented from misetching.

Referring to FIG. 18, the overall resist film 132 employed for forming the substrate contact holes 126 is removed. As shown in FIG. 19, the interlayer insulation film is covered with a new resist film 133, which in turn is patterned. As shown in FIG. 20, the patterned resist film 133 is employed as a mask for selectively removing portions of the interlayer insulation film for defining the electrode contact 129 thereby forming an electrode contact hole 127, and the overall resist film 133 is removed. While two electrode contact holes are conceivably formed at this time as that for the peripheral circuit transistor and that formed in each memory cell transistor, FIG. 20 shows only the electrode contact hole 127 formed in the peripheral circuit transistor.

Thereafter the substrate contact holes 126 and the electrode contact hole 127 are filled up with conductor materials followed by formation of wiring layers having wires of aluminum or the like, thereby completing the flash memory comprising the substrate contacts 128 and the electrode contact 129 as shown in FIG. 13.

As hereinabove described, a substrate contact hole and an electrode contact hole are generally formed through different resist films. This is because a film structure on source and drain regions and that on a gate electrode differ from each other in formation of the contact holes when the self-aligned contact structure is employed. Particularly when a patterning insulator film formed on a gate electrode is formed by a nitride film, it follows that a thick nitride-based insulator film absent on the source and drain regions is located on the gate electrode.

In other words, the electrode contact hole is not yet completely formed upon complete formation of the substrate contact hole also when the substrate contact hole and the electrode contact hole are simultaneously formed by etching. Therefore, etching is so incompletely performed that the electrode contact hole does not reach the upper surface of the gate electrode. When etching is continuously performed to completely form the electrode contact hole, overetching takes place in the vicinity of the source and drain regions, leading to misetching of an element isolation film. In this case, the significance of the self-aligned contact structure is reduced.

Thus, the substrate contact hole and the electrode contact hole cannot be simultaneously formed through the same step but are separately formed through different etching steps. Therefore, fabrication steps are complicated and the fabrication cost is increased due to masks required for the different etching steps respectively.

Japanese Patent Laying-Open No. 11-284138 (1999) discloses a method of fabricating a semiconductor device capable of simplifying a contact hole forming step. In the method of fabricating a semiconductor device disclosed in this gazette, part of a nitride-based insulator film for protecting a gate electrode is previously removed before a step of depositing an interlayer insulation film, so that a substrate contact hole and an electrode contact hole can be simultaneously formed in a contact hole forming step.

In the method of fabricating a semiconductor device disclosed in the aforementioned gazette, however, an etching step for selectively removing part of the nitride-based insulator film located on the gate electrode must be separately provided, with requirement for an individual mask for this etching step. Therefore, this fabrication process for a semiconductor device has only an insufficient effect for reduction of the fabrication cost.

When an interlayer insulation film is formed by three layers including an oxide-based insulator film, a nitride-based insulator film and an oxide-based insulator film while forming a patterning insulator film provided on a gate electrode is formed by an oxide film in order to employ the self-aligned contact structure in the flash memory described as the prior art, the following problem also arises:

In a step of forming an electrode contact hole 127, a projection 124a of a nitride-based insulator film 124 results in an intermediate portion of the inner peripheral wall of the electrode contact hole 127 as shown in FIG. 21, due to difference between the etching rate for an oxide-based insulator film and that for the nitride-based insulator film 124. Therefore, it is difficult to stably fill up the electrode contact hole 127 with a contact metal in a subsequently carried out electrode contact forming step, leading to deterioration of the yield.

### SUMMARY OF THE INVENTION

An object of the present invention is to provide a method of fabricating a semiconductor device having a self-aligned source structure capable of simultaneously forming both of a substrate contact hole and an electrode contact hole without increasing the number of fabricating steps and reducing the number of masks.

Another object of the present invention is to provide a method of fabricating a semiconductor device, applicable not only to a semiconductor device having a self-aligned contact structure but also to a general semiconductor device, capable of forming a reliable contact on a gate electrode.

According to a first aspect of the present invention, a method of fabricating a semiconductor device having a self-aligned source structure forming a source line in a self-aligned manner with respect to a gate electrode is characterized by selectively simultaneously removing a portion including a prospective electrode contact hole forming region of an insulator film located on the gate electrode when removing an element isolation film between source regions for forming the source line thereby partially exposing the upper surface of the gate electrode.

According to a second aspect of the present invention, a method of fabricating a semiconductor device having a self-aligned source structure forming a source line in a self-aligned manner with respect to a gate electrode of a memory cell transistor is characterized by selectively simultaneously removing a portion including a prospective electrode contact hole forming region of an insulator film located on a gate electrode of a transistor of a peripheral circuit other than the memory cell transistor when removing an element isolation film between source regions for forming the source line thereby partially exposing the upper surface of the gate electrode of the transistor of the peripheral circuit.

According to a third aspect of the present invention, a method of fabricating a semiconductor device comprises a gate electrode forming step, a diffusion layer forming step, a first etching step, an interlayer insulation film deposition step, a second etching step and a contact forming step. The gate electrode forming step is carried out for forming a gate electrode having an insulator film located to cover the upper surface on the main surface of a semiconductor substrate. The diffusion layer forming step is carried out for forming source and drain regions on portions of the main surface of the semiconductor substrate holding the gate electrode therebetween. The first etching step is carried out for removing an element isolation film adjacent to the source region while simultaneously selectively removing a portion including a prospective electrode contact hole forming region of the insulator film thereby partially exposing the upper surface of the gate electrode. The interlayer insulation film deposition step is carried out for successively depositing an interlayer insulation film consisting of three layers including a first oxide-based insulator film, a nitride-based insulator film and a second oxide-based insulator film to cover the overall main surface of the semiconductor substrate. The second etching step is carried out for selectively removing the interlayer insulation film for simultaneously forming an electrode contact hole reaching the gate electrode and a substrate contact hole reaching the source and drain regions. The contact forming step is carried out for filling up the electrode contact hole and the substrate contact hole with conductor materials.

In the aforementioned method of fabricating a semiconductor device according to the third aspect of the present invention, the semiconductor substrate may include a memory cell region formed with a memory cell transistor and a peripheral circuit region formed with a transistor other than the memory cell transistor, the first etching step may include operation of selectively simultaneously removing a portion including a prospective electrode contact hole forming region of the insulator film located on a gate electrode of the transistor of the peripheral circuit region, and the second etching step may include operation of simultaneously forming an electrode contact hole and a substrate contact hole for the transistor of the peripheral circuit region.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view of a flash memory according to an embodiment of the present invention;

FIGS. 2 to 12 illustrate first to eleventh steps in a method of fabricating the flash memory according to the embodiment of the present invention;

FIG. 13 is a sectional view of a conventional flash memory;

FIGS. 14 to 20 illustrate first to seventh steps in a method of fabricating the conventional flash memory; and

FIG. 21 is a sectional view showing a state after formation of electrode contact holes for illustrating a problem in the conventional flash memory.

### DESCRIPTION OF THE PREFERRED EMBODIMENT

An embodiment of the present invention is now described with reference to the drawings. This embodiment is illustrated with reference to a flash memory comprising not only memory cells but also peripheral circuits on a silicon substrate. In this embodiment, electrode contact holes are formed on gate electrodes of each memory cell transistor and each peripheral circuit transistor simultaneously with a substrate contact hole. The electrode contact hole of the peripheral circuit transistor is particularly shown in the drawings.

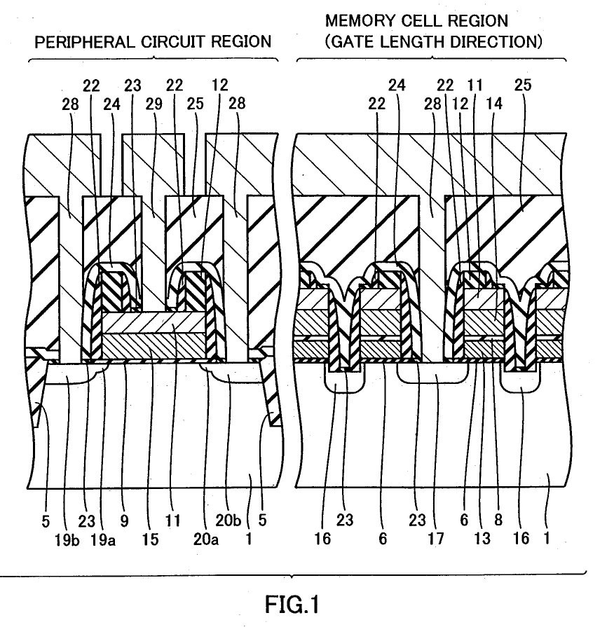

The structure of the flash memory according to the embodiment of the present invention is now described with reference to FIG. 1. The gate electrode of each memory cell transistor formed on a memory cell region consists of a floating gate electrode 13 located on the main surface of the silicon substrate 1 through a tunnel oxide film 6 and a control gate electrode 14 located on the floating gate electrode 13 through an ONO film 8 consisting of an oxide film, a nitride film and an oxide film. The upper portion of the control gate electrode 14 is covered with a tungsten silicide film 11.

The upper surface and the side surfaces of the gate electrode of the memory cell transistor having the aforementioned structure are covered with an insulator film 12 for patterning the gate electrode and side wall insulator films 22 respectively. The patterning insulator film 12 and the side wall insulator films 22 are formed by oxide-based insulator films. When the self-aligned contact structure is employed for forming a substrate contact in a self-aligned manner with respect to the gate electrode, multilayer films consisting of oxide-based insulator films and nitride-based insulator films formed thereon are employed as the patterning insulator film 12 and the side wall insulator films 22.

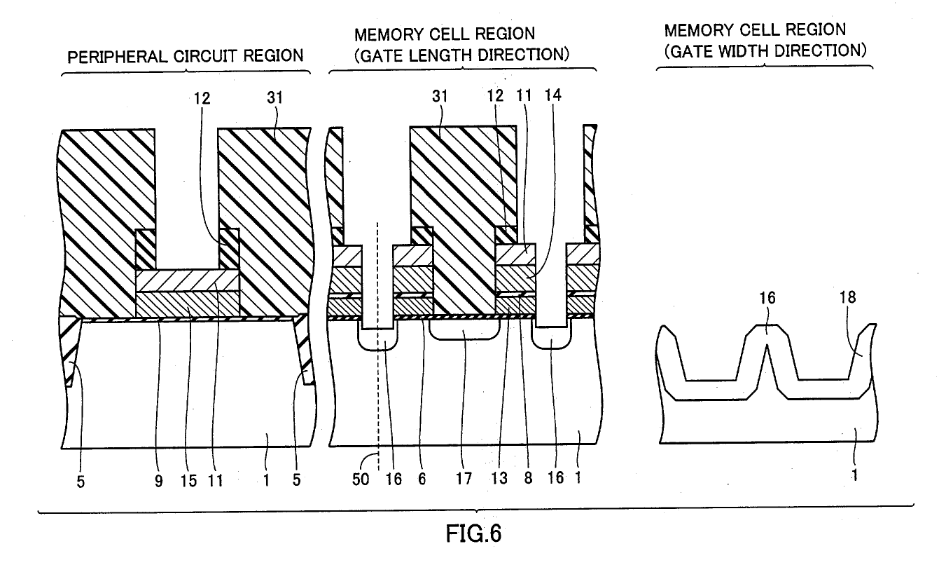

A source region 16 and a drain region 17 are provided on portions of the main surface of the silicon substrate 1 holding the gate electrode of each memory cell transistor therebetween. A substrate contact 28 is individually formed on the drain region 17 every memory cell, and connected to a corresponding bit line. No substrate contact is provided on the source region 16, which is connected to a source region adjacent thereto perpendicularly to the plane of FIG. 1 by a source line 18 serving as a diffusion layer wire (see FIG. 6).

A gate electrode 15 of the peripheral circuit transistor formed on a peripheral circuit region is located on the main surface of the silicon substrate 1 through a tunnel oxide film 9. The structure of the gate electrode 15 of the peripheral circuit transistor corresponds to that of a general MOS transistor, dissimilarly to the structure of that of the aforementioned memory cell transistor. The upper portion of the gate electrode 15 of the peripheral circuit transistor is also covered with a tungsten silicide film 11.

The upper surface and the side surfaces of the gate electrode 15 of the peripheral circuit transistor having the aforementioned structure are covered with an insulator film 12 for patterning the gate electrode 15 and side wall insulator films 22 respectively. The patterning insulator film 12 and the side wall insulator films 22 are formed by oxide-based insulator films. When the self-aligned contact structure is employed for forming a substrate contact in a self-aligned manner with respect to the gate electrode 15, multilayer films consisting of oxide-based insulator films and nitride-based insulator films are employed in place of the oxide-based insulator films. The patterning insulator film 12 remaining on the upper surface of the gate electrode 15 is partially removed, as described later.

Source regions 19a and 19b and drain regions 20a and 20b are provided on portions of the main surface of the silicon substrate 1 holding the gate electrode 15 of the peripheral circuit transistor therebetween. Substrate contacts 28 are formed on the source regions 19a and 19b and the drain regions 20a and 20b respectively and connected to wires corresponding thereto. In the peripheral circuit transistor, no self-aligned source structure is employed for connecting the source regions 19a and 19b to other source regions, and hence the substrate contact 28 is individually formed on the source regions 19a and 19b.

The substrate contacts 28 of the aforementioned memory cell transistor and the aforementioned peripheral circuit transistor and an electrode contact 29 are formed to pass through an interlayer insulation film deposited to cover the upper portions of the gate electrodes and the main surface of the silicon substrate 1. In order to prevent an element isolation film from misetching by the self-aligned contact structure, the interlayer insulation film is formed by three layers including a first oxide-based insulator film 23, a nitride-based insulator film 24 and a second oxide-based insulator film 25. The nitride-based insulator film 24 is formed for preventing the element isolation film from misetching in a substrate contact hole forming step when the aforementioned self-aligned contact structure is employed, and the first oxide-based insulator film 23 serves as an underlayer for the nitride-based insulator film 24.

As hereinabove described, the patterning insulator film 12 located on the gate electrode 15 of the peripheral circuit transistor is partially removed. The removed part of the patterning insulator film 12 is filled up with the interlayer insulation film. The electrode contact 29 reaches the upper surface of the gate electrode 15 through the part filled up with the interlayer insulation film. Therefore, the interlayer insulation film is located between the patterning insulator film 12 and the electrode contact 29. The part filled up with the interlayer insulation film is in contact with the tungsten silicide film 11 forming the upper surface of the gate electrode 15.

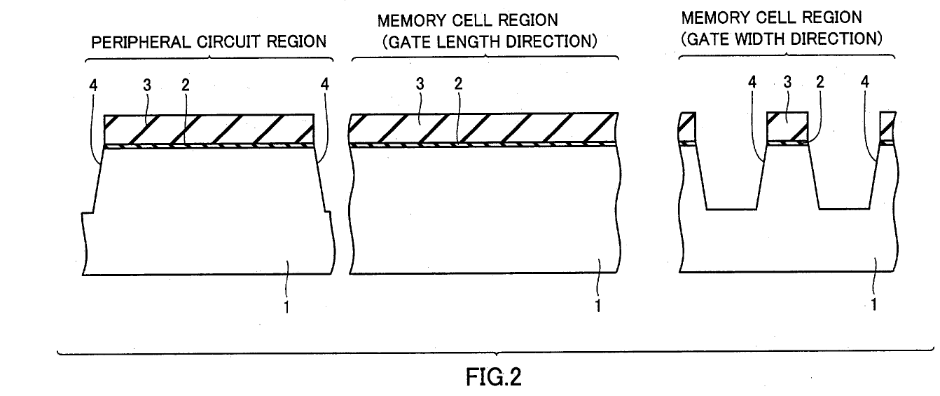

Steps of fabricating the flash memory having the aforementioned structure are now described in detail. Referring to FIG. 2, an oxide film 2 of about 200 Å in thickness is formed on the overall main surface of the silicon substrate 1 by thermal oxidation. A nitride film 3 of about 2000 Å in thickness is deposited on this oxide film 2. Thereafter the nitride film 3 and the oxide film 2 are dry-etched through a resist mask patterned at a prescribed pitch. The resist film is removed and the silicon substrate 1 is dry-etched through the patterned nitride film 3 and the patterned oxide film 2 serving as masks, for forming trenches 4 of about 3000 Å in depth.

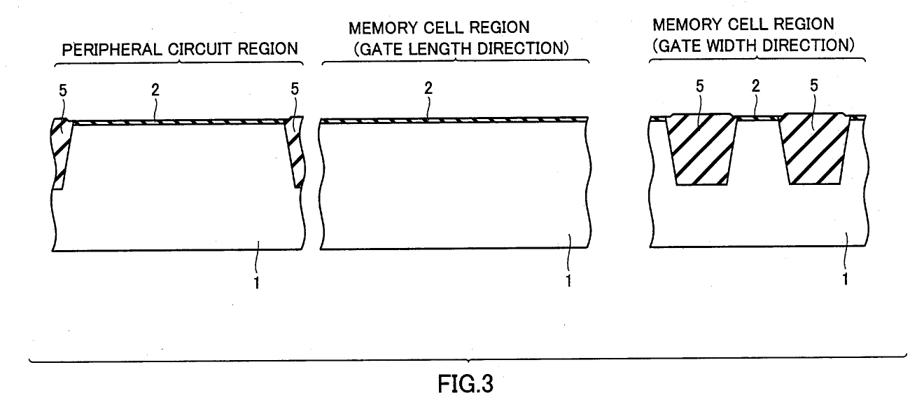

Then, inner wall oxide films of about 300 Å are formed by thermally oxidizing the inner walls of the trenches 4, in order to prevent corners of the trenches 4 from electric field concentration. Then, a buried oxide film for partially forming element isolation films is deposited by about 5000 Å, to fill up the trenches 4. The surface of the buried oxide film is flattened by CMP (chemical mechanical polishing), and thereafter the buried oxide film is wet-etched by a prescribed quantity with dilute fluoric acid. The nitride film 3 is removed with hot phosphoric acid. Thus, trench element isolation films 5 are formed as shown in FIG. 3.

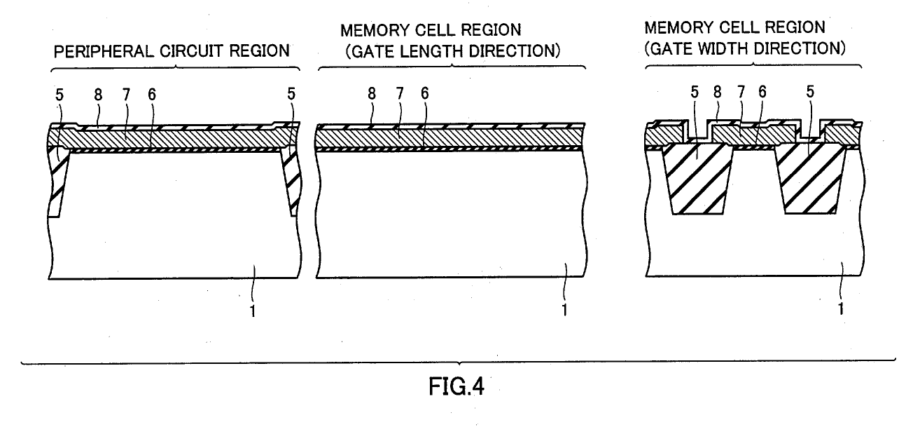

Then, ions are implanted into the silicon substrate 1 under prescribed conditions for forming an n well layer and a p well layer, and the oxide film 2 is removed with dilute fluoric acid. Further, an oxide film 6 for defining the tunnel oxide film 6 of the memory cell transistor is grown by about 100 Å by thermal oxidation, and a phosphorized polysilicon layer 7 for defining the floating gate electrode 7 of the memory cell transistor is deposited by about 1000 Å. Thereafter the phosphorized polysilicon layer 7 is dry-etched through a resist film patterned at a prescribed pitch for serving as a mask, thereby patterning the floating gate electrode 7 in the gate width direction. Then, the resist film is removed and the surface of the phosphorized polysilicon layer 7 is thermally oxidized for forming an oxide film of about 50 Å followed by deposition of a nitride film and an oxide film, thereby forming the ONO film 8 consisting of the three layers including the oxide film, the nitride film and the oxide film. Thus, a structure shown in FIG. 4 is obtained.

Then, the memory cell transistor region is covered with a resist film for removing portions of the phosphorized polysilicon layer 7 and the ONO film 8 located on the peripheral circuit region as well as the portion of the oxide film 6 located under the same by dry etching, and the resist film is removed.

Then, a phosphorized polysilicon layer 10 for defining the control gate electrode 14 of the memory cell transistor and the gate electrode 15 of the peripheral circuit transistor is deposited by about 1000 Å, followed by deposition of the tungsten silicide film 11. The insulator film 12 consisting of an oxide film of about 2000 Å is deposited, and thereafter photolithography is performed for patterning the insulator film 12. The patterned insulator film 12 is employed as a mask for patterning the control gate electrode 14 of the memory cell transistor and the gate electrode 15 of the peripheral circuit transistor. Thus, the multilayer electrode consisting of the floating gate electrode 13 and the control gate electrode 14 is formed on the memory cell region while the gate electrode 15 corresponding to that of a general MOS transistor is formed on the peripheral circuit region.

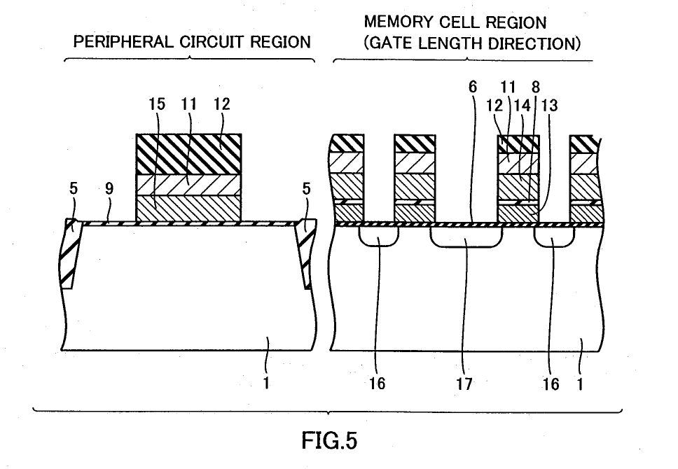

Then, the source region 16 and the drain region 17 of the memory cell transistor are formed by ion implantation, thereby obtaining a structure shown in FIG. 5. In order to form the substrate contact 28 in a self-aligned manner with respect to the control gate electrode 14 of the memory cell transistor, the patterning insulator film 12 is formed by an underlayer oxide film of about 100 Å and a nitride film of about 1900 Å in place of the aforementioned oxide film of about 2000 Å.

Referring to FIG. 6, the overall peripheral circuit region and the drain region 17 of the memory cell region are covered with a resist film 31 for removing the element isolation film located between the source region 16 and another source region of the memory cell region by etching through the resist film 31 and the patterning insulator film 12 serving as masks. At this time, a portion of the patterning insulating film 12, located on the gate electrode 15 of the peripheral circuit transistor, including a prospective electrode contact hole forming region is also simultaneously removed.

Then, ions are implanted into the portion of the main surface of the silicon substrate 1 from which the element isolation film is removed, thereby forming a diffusion layer having a conductivity type corresponding to the source region 16. Thus, the source line 18 connecting the source region 16 with that adjacent thereto along the gate width direction is formed as shown in FIG. 6. The section of the memory cell region in the gate width direction shown in FIG. 6 is taken along a dotted line 50 on the section of the memory cell region along the gate length direction.

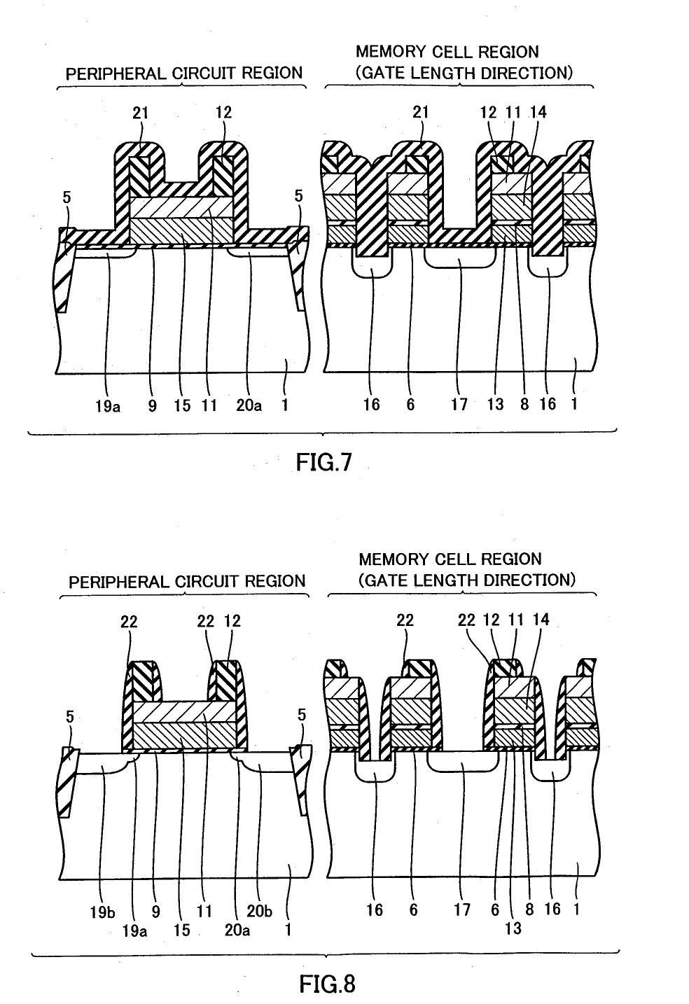

Referring to FIG. 7, the resist film 31 is removed and extension layers 19a and 20a partially defining the source and drain regions 19a and 20a of the peripheral circuit transistor are formed by ion implantation. Thereafter an oxide film 21 of 2000 Å for forming the side wall insulator films 22 is deposited on the overall main surface of the silicon substrate 1. In order to form the substrate contact 28 in a self-aligned manner with respect to the control gate electrode 14 of the memory cell transistor, an underlayer oxide film of about 100 Å and a nitride film of about 1900 Å are successively stacked in place of the aforementioned oxide film of about 2000 Å.

Referring to FIG. 8, the oxide film 21 is etched back for forming the side wall insulator films 22. Thereafter the side wall insulator films 22 and the patterning insulator film 12 are employed as masks for performing ion implantation, thereby forming diffusion layers 19b and 20b for forming the source and drain regions 19b and 20b of the peripheral circuit transistor.

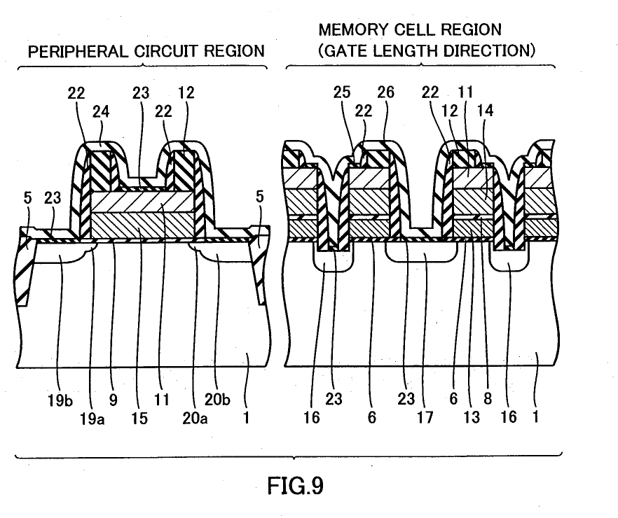

Thereafter the first oxide-based insulator film 23 of about 100 Å and the nitride-based insulator film 24 of about 500 Å are successively deposited on the overall main surface of the silicon substrate 1, as shown in FIG. 9. The first oxide-based film 23 serves as the underlayer for the nitride-based insulator film 24 deposited thereon, and the nitride-based insulator film 24 is employed for forming substrate contact holes in a self-aligned manner with respect to the source region 16 and the drain region 17 in a later contact hole forming step. The nitride-based insulator film 24 is formed under the interlayer insulation film, thereby preventing the element isolation films from misetching also when a mask is misaligned.

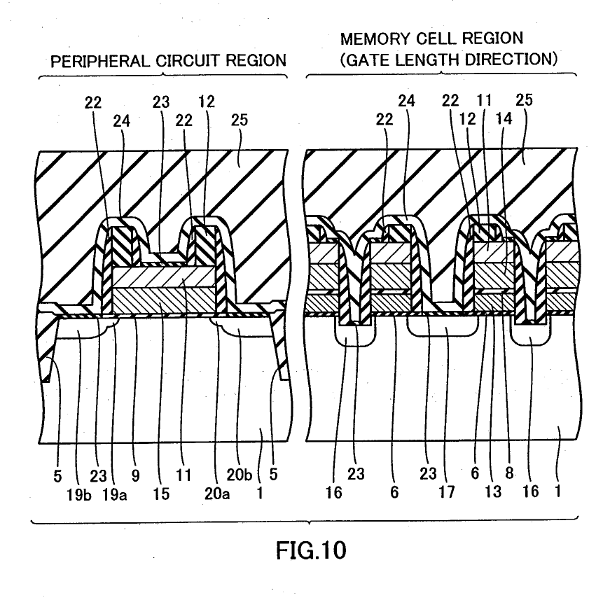

As shown in FIG. 10, the second oxide-based insulator film 25 of about 7000 Å is deposited on the nitride-based insulator film 24 for forming the interlayer insulation film consisting of the three layers including the first oxide-based insulator film 23, the nitride-based insulator film 24 and the second oxide-based insulator film 25. The second oxide-based insulator film 25 serves as a spacer film keeping the distance between the layers.

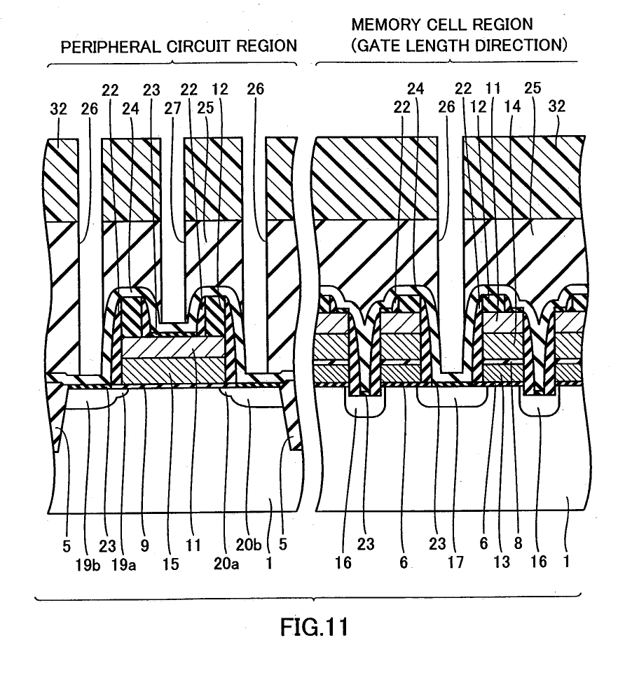

Referring to FIG. 11, a patterned resist film 32 is deposited on the interlayer insulation film and employed as a mask for selectively removing portions of the second oxide-based insulator film 25 for forming the substrate contacts 28 and the electrode contact 29 by etching. At this time, the second oxide-based insulator film 25 is etched under etching conditions having selectivity for the nitride-based insulator film 24, and the etching is temporarily stopped by the nitride-based insulator film 24.

Then, portions of the remaining nitride-based insulator film 24 and the first oxide-based insulator film 23 for forming the substrate contacts 28 and the electrode contact 29 are removed under etching conditions, different from the aforementioned etching conditions, capable of etching the nitride-based insulator film 24 and the first oxide-based insulator film 23. Substrate contact holes 26 and an electrode contact hole 27 are formed by two-stage etching as hereinabove described, whereby the quantity of overetching can be suppressed as compared with a case of performing the aforementioned etching at a time, thereby preventing the element isolation film adjacent to the formed substrate contact hole 26 from misetching.

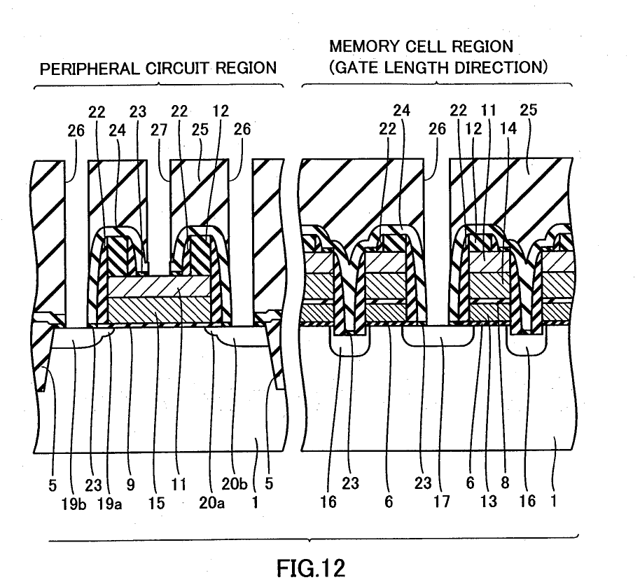

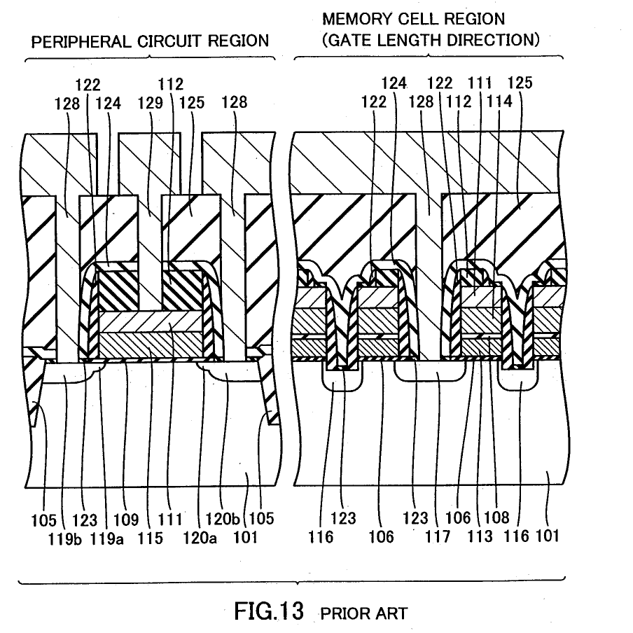

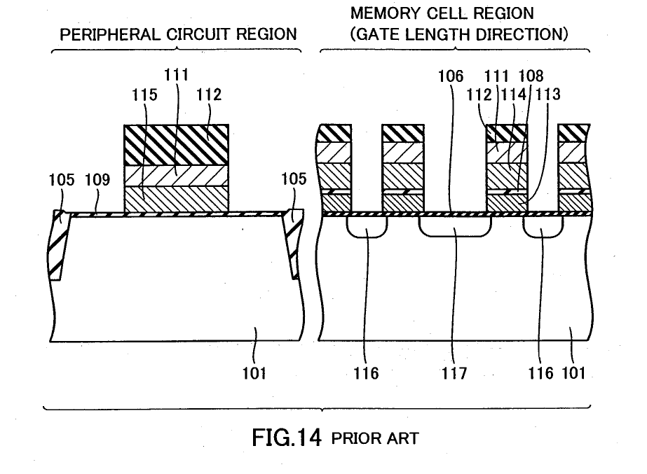

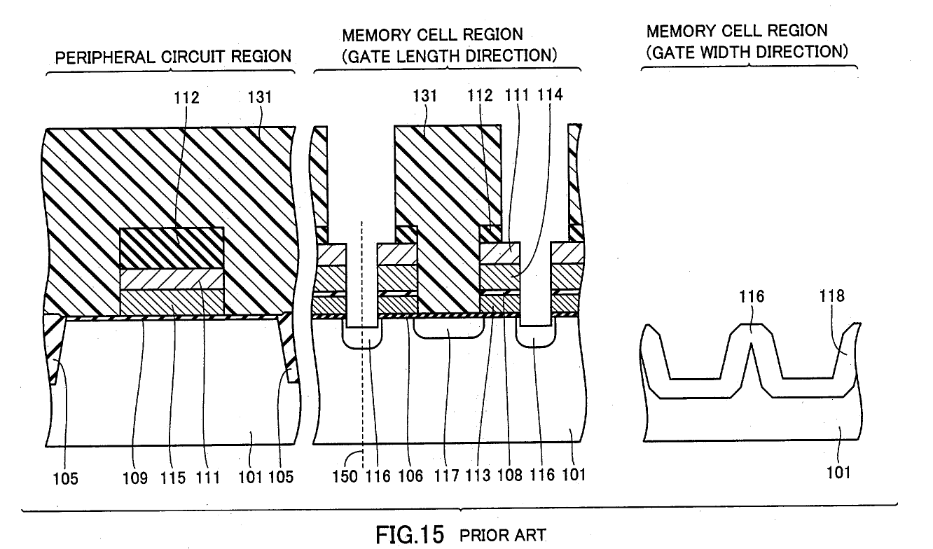

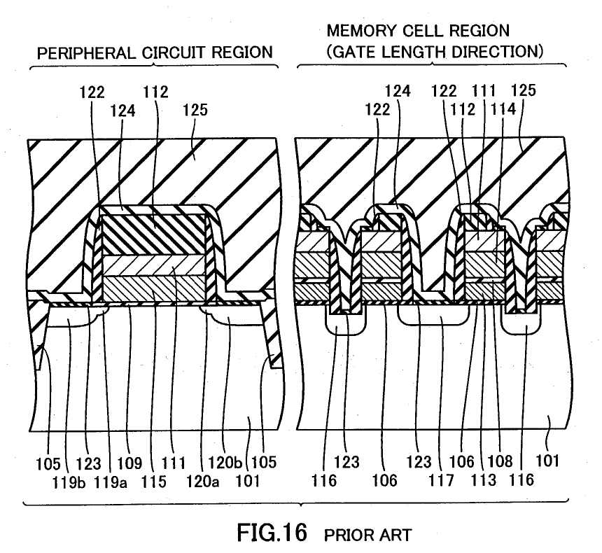

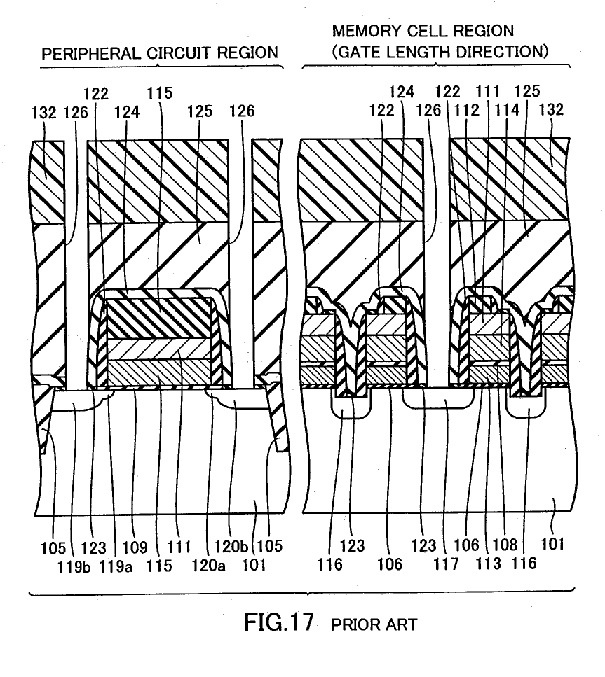

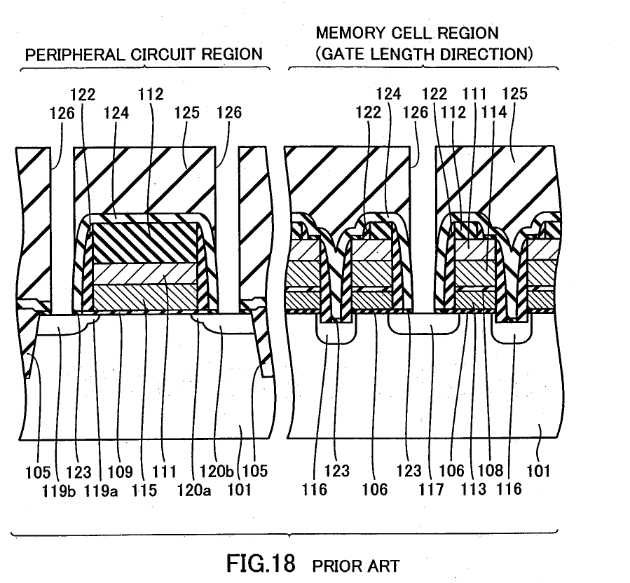

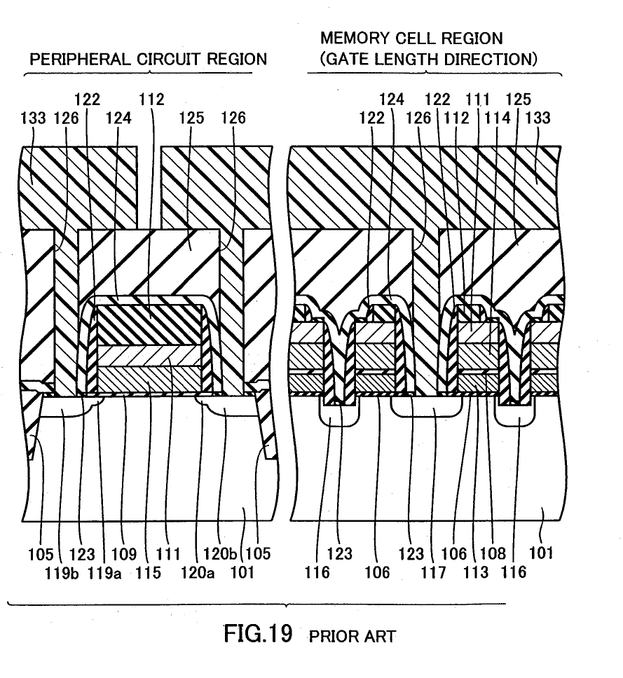

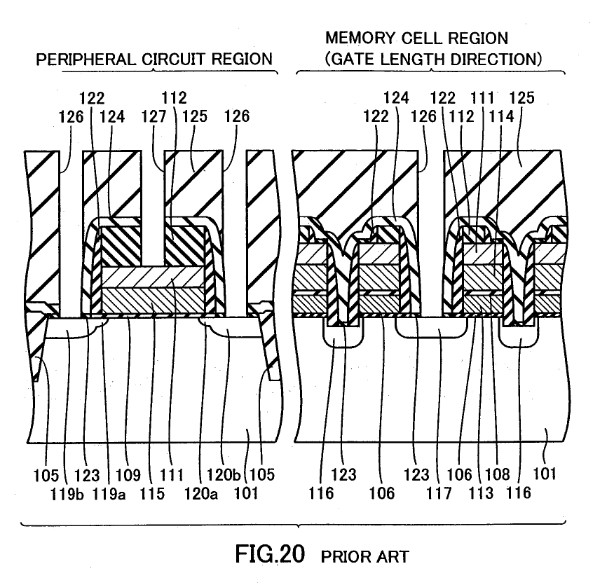

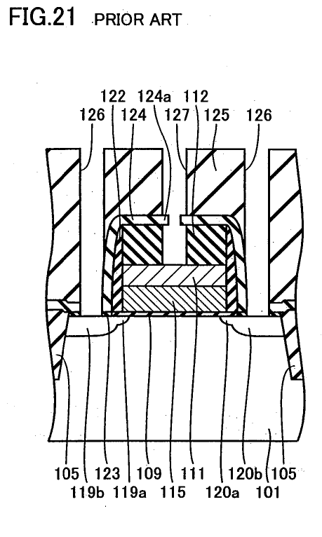

As shown in FIG. 12, the overall resist film 32 is removed, the substrate contact holes 26 and the electrode contact hole 27 are filled up with conductor materials and wiring layers having wires of aluminum or the like are formed thereby completing the flash memory comprising the substrate contacts 28 and the electrode contact 29 as shown in FIG. 1.

As hereinabove described, a portion including a prospective electrode contact forming region of a patterning insulator film located on a gate electrode of a peripheral circuit transistor to be formed with an electrode contact is simultaneously removed in an etching step for an element isolation film for forming the self-aligned source structure, whereby the structure and the thickness of an etched film located on the gate electrode are substantially similar to those of etched films located on a source region and a drain region in formation of contact holes so that a substrate contact hole and an electrode contact hole can be simultaneously formed through a single etching step. According to this method, an insulator film located on a gate electrode can also be selectively simultaneously removed in a step of removing the element isolation film for forming the self-aligned source structure, whereby neither the number of fabrication steps nor the number of masks is increased as compared with the prior art. Thus, the fabrication cost can be remarkably reduced.

The portion including the prospective electrode contact hole forming region of the patterning insulator film is removed and the remaining portion is covered with an interlayer insulation film, whereby no projection of a nitride film results in an intermediate portion of the inner peripheral wall of an electrode contact in formation of the electrode contact hole also when the interlayer insulation film is formed by three layers including an oxide-based insulator film, a nitride-based insulator film and an oxide-based insulator film. Therefore, the electrode contact hole can be stably filled up with a contact metal, for enabling formation of a highly reliable electrode contact. This structure is applicable not only to a semiconductor device having the aforementioned self-aligned source structure but also to a general semiconductor device such as a DRAM.

While the electrode contact hole 27 of the transistor formed on the peripheral circuit region is illustrated as that formed simultaneously with the substrate contact holes 26 in the aforementioned embodiment, it is also possible to simultaneously form an electrode contact hole of the memory cell transistor, as a matter of course. In this case, a portion including a prospective electrode contact hole forming region of the insulator film located on the gate electrode of the memory cell transistor to be formed with the electrode contact 29 is simultaneously removed in the etching step for the element isolation film for forming the self-aligned source structure of the memory cell transistor.

While the above embodiment has been described with reference to the flash memory comprising not only the memory cell region formed with the memory cell transistor but also the peripheral circuit region formed with the peripheral circuit transistor, the present invention is not particularly restricted to this but is also applicable to a semiconductor device having only memory cells formed on a semiconductor substrate, as a matter of course.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A method of fabricating a semiconductor device having a self-aligned source structure forming a source line in a self-aligned manner with respect to a gate electrode,
selectively simultaneously removing a portion including a prospective electrode contact hole forming region of an insulator film located on said gate electrode when removing an element isolation film between source regions for forming said source line thereby partially exposing the upper surface of said gate electrode.

2. A method of fabricating a semiconductor device having a self-aligned source structure forming a source line in a self-aligned manner with respect to a gate electrode of a memory cell transistor,
selectively simultaneously removing a portion including a prospective electrode contact hole forming region of an insulator film located on a gate electrode of a transistor of a peripheral circuit other than said memory cell transistor when removing an element isolation film between source regions for forming said source line thereby partially exposing the upper surface of said gate electrode of said transistor of said peripheral circuit.

3. A method of fabricating a semiconductor device, comprising:
a gate electrode forming step of forming a gate electrode having an insulator film located to cover the upper surface on the main surface of a semiconductor substrate;
a diffusion layer forming step of forming source and drain regions on portions of the main surface of said semiconductor substrate holding said gate electrode therebetween;
a first etching step of removing an element isolation film adjacent to said source region while simultaneously selectively removing a portion including a prospective electrode contact hole forming region of said insulator film thereby partially exposing the upper surface of said gate electrode;
an interlayer insulation film deposition step of successively depositing an interlayer insulation film consisting of three layers including a first oxide-based insulator film, a nitride-based insulator film and a second oxide-based insulator film to cover the overall main surface of said semiconductor substrate;
a second etching step of selectively removing said interlayer insulation film for simultaneously forming an electrode contact hole reaching said gate electrode and a substrate contact hole reaching said source and drain regions; and
a contact forming step of filling up said electrode contact hole and said substrate contact hole with conductor materials.

4. The method of fabricating a semiconductor device according to claim 3, wherein
said second etching step includes steps of removing said second oxide-based insulator film located on said nitride-based insulator film with an etching condition having selectivity for said nitride-based insulator film and removing said nitride-based insulator film and said first oxide-based insulator film with a condition different from said etching condition.

5. The method of fabricating a semiconductor device according to claim 3, wherein
said insulator film located to cover the upper surface of said gate electrode is a two-layer insulator film formed by successively depositing an oxide-based insulator film and a nitride-based insulator film.

6. The method of fabricating a semiconductor device according to claim 3, wherein
said semiconductor substrate includes a memory cell region formed with a memory cell transistor and a peripheral circuit region formed with a transistor other than said memory cell transistor,
said first etching step includes operation of selectively simultaneously removing a portion including a prospective electrode contact hole forming region of said insulator film located on a gate electrode of said transistor of said peripheral circuit region, and
said second etching step includes operation of simultaneously forming an electrode contact hole and a substrate contact hole for said transistor of said peripheral circuit region.
